(19) United States
(12) Patent Application Publication
(10) Pub. No.: US 2025/0287736 A1
(43) Pub. Date: Sep. 11, 2025

(54) LED WAFER, CARRIER SUBSTRATE FOR LED CHIP, MANUFACTURING METHOD FOR DISPLAY DEVICE, AND REPAIR METHOD FOR DISPLAY DEVICE

(71) Applicant: Japan Display Inc., Tokyo (JP)

(72) Inventor: Kazuyuki YAMADA, Tokyo (JP)

(21) Appl. No.: 19/051,525

(22) Filed: Feb. 12, 2025

(30) Foreign Application Priority Data
Mar. 8, 2024 (JP) 2024-036152

(51) Int. Cl. H10H 20/831; H01L 25/075; H10H 20/01; H10H 20/817; H10H 20/857

(52) U.S. Cl. CPC H10H 20/8312; H01L 25/0753; H10H 20/019; H10H 20/817; H10H 20/857

(57) ABSTRACT

An LED wafer includes at least one LED element stack including a first semiconductor layer having a first conductivity type, a light-emitting layer, and a second semiconductor layer having a second conductivity type opposite to the first conductivity type stacked on a crystalline substrate, at least one terminal electrode forming a contact with the first semiconductor layer or the second semiconductor layer, and at least one conductive bonding material layer on the terminal electrode.

### CROSS-REFERENCE TO RELATED APPLICATIONS

This application claims the benefit of priority to Japanese Patent Application No. 2024-036152, filed on Mar. 8, 2024, the entire contents of which are incorporated herein by reference.

### FIELD

One embodiment of the present invention relates to an LED (Light Emitting Diode) wafer, a carrier substrate for an LED chip, a manufacturing method for a display device, and a repair method for a display device.

### BACKGROUND

Recently, an LED display in which a minute LED (so-called micro-LED) is mounted on each pixel has been developed as a next-generation display device. An LED display has a structure in which a plurality of LED chips is mounted on a circuit board constituting a pixel array. The circuit board has a drive circuit for causing an LED to emit light at a position corresponding to each pixel. These drive circuits are electrically connected to each LED chip, respectively.

When mounting a plurality of LED chips on a circuit board, a poor connection between each LED and electrodes on the circuit board may occur. Patent document 1 (refer to U.S. patent Ser. No. 10/096,740) discloses that in order to improve the reliability of display devices, when a plurality of LED chips is mounted on a circuit board, the LEDs are checked non-destructively to see if there is a connection failure between the LEDs and the circuit board.

For a display device with mounted LED chips, there is a need to improve the yield rate when mounting the LED chips from the carrier substrate on which they are formed to the circuit board. For example, laser light is used to bond the LED chip to the circuit board as in the conventional technology, but if a poor connection occurs between the LED chip and the circuit board, the yield rate will be reduced.

### SUMMARY

An LED wafer in an embodiment according to the present invention includes at least one LED element stack including a first semiconductor layer having a first conductivity type, a light-emitting layer, and a second semiconductor layer having a second conductivity type opposite to the first conductivity type stacked on a crystalline substrate, at least one terminal electrode forming a contact with the first semiconductor layer or the second semiconductor layer, and at least one conductive bonding material layer on the terminal electrode.

A carrier substrate for an LED chip in an embodiment according to the present invention includes a carrier substrate, and at least one LED chip on the carrier substrate, and an adhesive layer between the carrier substrate and the at least one LED chip, wherein the at least one LED chip includes a semiconductor layer in which a first semiconductor layer having a first conductivity type, a light-emitting layer, and a second semiconductor layer having a second conductivity type opposite to the first conductivity type are stacked, at least one terminal electrode forming a contact with the first semiconductor layer or the second semiconductor layer, and a conductive bonding material layer on the terminal electrode, wherein the at least one LED chip is arranged on the carrier substrate with a surface on which the conductive bonding material layer is provided as a top surface, and the at least one LED chip is fixed to the carrier substrate by the adhesive layer.

A manufacturing method for a display device in an embodiment according to the present invention includes aligning a carrier substrate for an LED chip including a carrier substrate, at least one LED chip on the carrier substrate, a conductive bonding material layer on a first surface of the at least one LED chip, and an adhesive layer on a second surface of the at least one LED chip, and a circuit board having a pixel region so as to overlap the at least one LED chip in a plan view, and mounting the at least one LED chip in the pixel region.

A repair method for a display device in an embodiment according to the present invention includes removing a first LED chip determined to be defective among a plurality of LED chips, the defective LED chip being arranged on a mounting pad at a first point of a first pixel in a pixel region, aligning a conductive bonding material layer and the mounting pad to overlap, in which a carrier substrate of an LED chip including at least one LED chip on the carrier substrate, the conductive bonding material layer on a first surface of the at least one LED chip, an adhesive layer on a second surface of the at least one LED chip, removing the at least one LED chip from the carrier substrate, and fusing the at least one LED chip to the mounting pad by melting and curing at least a part of the conductive bonding material layer.

### BRIEF DESCRIPTION OF DRAWINGS

FIG. 1 is a plan view of an LED wafer according to one embodiment of the present invention.

FIG. 2 is a cross-sectional view showing a portion of an LED wafer according to one embodiment of the present invention.

FIG. 3 is a plan view showing an LED wafer according to one embodiment of the present invention.

FIG. 4 is a cross-sectional view showing a portion of an LED wafer according to one embodiment of the present invention.

FIG. 5 is a plan view showing a carrier substrate of an LED chip according to one embodiment of the present invention.

FIG. 6 is a plan view of a carrier substrate for an LED chip according to one embodiment of the present invention.

FIG. 7 is a cross-sectional view showing a portion of the carrier substrate for an LED chip according to one embodiment of the present invention.

FIG. 8 is a plan view showing a carrier for an LED chip according to one embodiment of the present invention.

FIG. 9 is a cross-sectional view showing a portion of a carrier substrate for an LED chip according to one embodiment of the present invention.

FIG. 10 is a flowchart diagram showing a manufacturing method of a display device according to one embodiment of the present invention.

FIG. 11 is a plan view showing a manufacturing method for a display device according to one embodiment of the present invention.

FIG. 12 is a cross-sectional view showing a manufacturing method for a display device according to an embodiment of the present invention.

FIG. 13 is a cross-sectional view showing a manufacturing method for a display device according to one embodiment of the present invention.

FIG. 14 is a flowchart diagram showing a repair method for a display device according to one embodiment of the present invention.

FIG. 15 is a cross-sectional view showing a repair method for a display device according to one embodiment of the present invention.

FIG. 16 is a cross-sectional view showing a repair method for a display device according to one embodiment of the present invention.

FIG. 17 is a cross-sectional view showing a repair method for a display device according to one embodiment of the present invention.

### DESCRIPTION OF EMBODIMENTS

Embodiments of the present invention will be described below with reference to the drawings and the like. However, the present invention can be implemented in various modes without departing from the gist thereof. The present invention is not to be construed as being limited to the description of the following exemplary embodiments. For the sake of clarity of description, the drawings may be schematically represented with respect to widths, thicknesses, shapes, and the like of the respective portions in comparison with actual modes. However, the drawings are merely examples and do not limit the interpretation of the present invention.

In describing the present embodiment, a direction from a substrate to an LED chip is “above” and the opposite direction is “below”. However, the expression “above” or “below” merely describes the upper limit relationship of each element. For example, the expression that an LED chip is arranged above a substrate also includes the presence of other members between the substrate and the LED chip. Furthermore, the expression “above” or “below” includes not only the case where chips overlap but also the case where they do not overlap in a plan view.

In the description of the embodiment of the present invention, elements having the same functions as those of the elements already described are denoted by the same symbols or the same symbols with symbols such as letters of the alphabet, and the description thereof may be omitted.

### First Embodiment

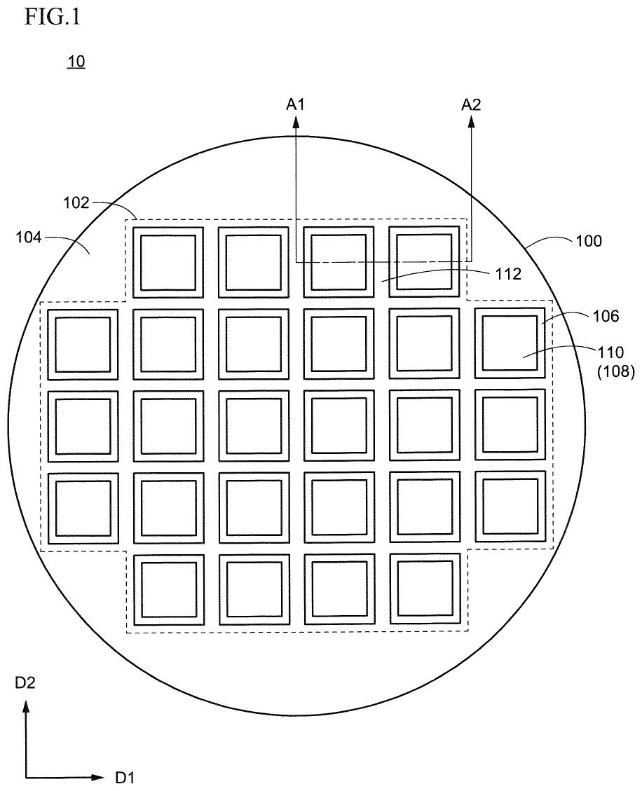

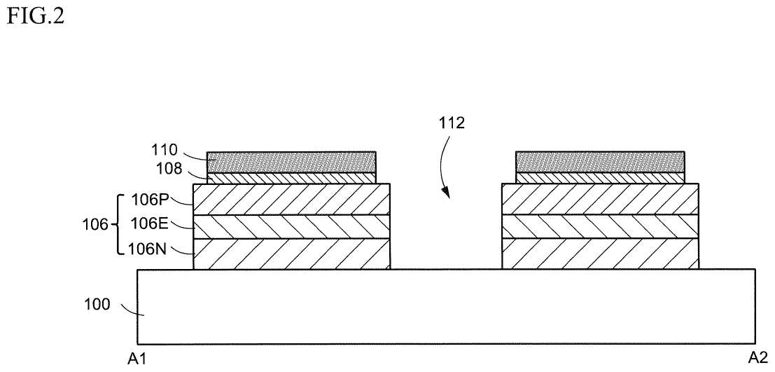

An LED wafer 10 which is one of the embodiments of the present invention will be described while referring to FIGS. 1 and 2.

FIG. 1 is a plan view of the LED wafer 10 of one embodiment of the present invention. The LED wafer 10 includes a crystalline substrate 100, an LED element stack 106, a terminal electrode 108, and a conductive bonding material layer 110.

The crystalline substrate 100 has a region 102 in which the LED element stack 106 is arranged and a peripheral region 104 surrounding the region 102. A plurality of LED element stacks 106 are aligned in a first direction D1 (row direction) and a second direction (column direction) shown in FIG. 1, and are arranged in a matrix. The peripheral area 104 may be provided with a marker or the like for use in transferring the LED element stack 106 to other substrates.

The LED element stack 106 is provided with a terminal electrode 108 and a conductive bonding material layer 110. The terminal electrode 108 may be provided in the LED element stack 106, as shown in FIG. 1. The shape of the terminal electrode 108 may be adjusted to the shape of the LED element stack 106 in a plan view. The conductive bonding material layer 110 may be provided within the terminal electrode 108, as shown in FIG. 1. The shape of the conductive bonding material layer 110 may be adjusted to the shape of the terminal electrode 108 in a plan view.

In FIG. 1, a rectangular shape is shown for each of the LED element stack 106, the terminal electrode 108, and the conductive bonding material layer 110, but the shape of each is not limited to rectangular and may be any shape.

FIG. 2 is a cross-sectional view of a portion of an LED wafer. Specifically, FIG. 2 is an enlarged cross-sectional view cut along the line A1-A2 shown in FIG. 1.

As shown in FIG. 2, the LED element stack 106 is provided on the crystalline substrate 100. At least one terminal electrode 108 may be provided on the LED element stack 106. A conductive bonding material layer 110 is provided on the terminal electrode 108. The conductive bonding material layer 110 may be arranged to sandwich the crystalline substrate 100 and the LED element stack 106.

The crystalline substrate 100 can support each layer provided on the crystalline substrate 100. The crystalline substrate 100 should preferably be a substrate on which a first semiconductor layer 106N, a second semiconductor layer 106P, and a light-emitting layer 106E included in the LED element stack 106 can grow crystals. For example, a sapphire substrate, a gallium nitride substrate, or a silicon carbide substrate may be used as the crystalline substrate 100.

The LED element stack 106 includes a first semiconductor layer 106N having a first conductivity type, a light-emitting layer 106E, and a second semiconductor layer 106P having a second conductivity type opposite to the first conductivity type described above, stacked on the crystalline substrate 100. The first semiconductor layer 106N is arranged on the crystalline substrate 100. The light emitting layer 106E is arranged on the first semiconductor layer 106N. The second semiconductor layer 106P is arranged on the light emitting layer 106E. The plurality of LED element stacks 106 may be separated from each other by a separation groove 112, as shown in FIGS. 1 and 2. The separation groove 112 can be formed by a treatment process such as etching.

The first semiconductor layer 106N is, for example, a layer formed of an n-type semiconductor, and the second semiconductor layer 106P is, for example, a layer formed of a p-type semiconductor. For example, gallium nitride can be used for the n-type semiconductor layer 106N and p-type semiconductor layer 106P. For example, a material including indium, gallium, and nitrogen can be used for the light-emitting layer 106E, and may have a quantum well structure. The emission color of the light-emitting layer 106E may be changed by adjusting the composition ratio of indium and gallium.

The terminal electrode 108 forms a contact with the second semiconductor layer 106P. The terminal electrode 108 can be directly or electrically connected to the second semiconductor layer 106P. The terminal electrode 108 can be a conductive material such as gold (Au), copper (Cu), silver (Ag), tin (Sn), aluminum (Al), and the like.

The conductive bonding material layer 110 is a conductive layer for connecting the LED element stack 106 to a circuit board 30, which will be described later, and is provided on the LED element stack 106. The conductive bonding material layer 110 can be, for example, a conductive material such as silver paste, solder (Sn), a paste containing metal nanoparticles, or an anisotropic conductive film (ACF).

In one embodiment of the present invention described above, the LED element stack 106 is a so-called vertical structure LED element stack, in which the first semiconductor layer 106N having a first conductivity type, the light-emitting layer 106E, and the second semiconductor layer 106P having a second conductivity type opposite to the first conductivity type are stacked on the crystalline substrate 100, and the terminal electrode 108 forms a contact with the second semiconductor layer 106P. However, the connection between the LED element stack and the terminal electrode 108 is not limited to the connection of the vertical structure.

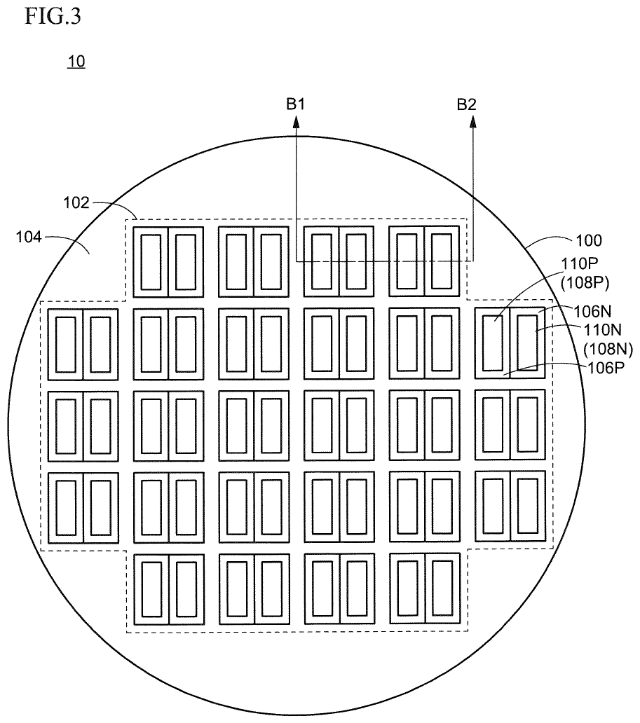

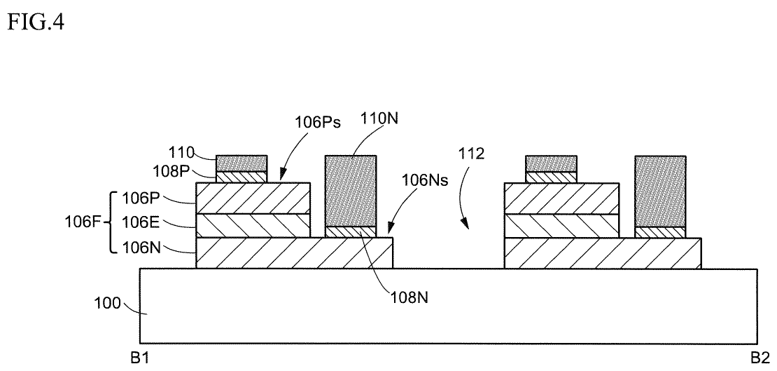

FIG. 3 is a plan view of an LED wafer according to one embodiment of the present invention. As shown in FIG. 3, the LED element stack 106 in the present embodiment has a flip-type structure with two terminal electrodes 108N and 108P in a planar view. In FIGS. 3 and 4, the same reference numbers are attached to the same configuration of the LED element stack 106 shown in FIGS. 1 and 2, and the succeeding explanations are omitted.

A LED element stack 106F includes, in a plan view, a region 106NS where the first semiconductor layer 106N is exposed and a region 106PS where the second semiconductor layer 106P is exposed, and include a first terminal electrode 108N and a second terminal electrode 108P. As shown in FIG. 3, the region 106NS in which the first semiconductor layer 106N is exposed may be adjacent to a region 106PS in which the second semiconductor layer 106P is exposed. The region 106NS in which the first semiconductor layer 106N is exposed may be arranged to surround the first terminal electrode 108N. The region 106PS in which the second semiconductor layer 106P is exposed may be arranged to surround the second terminal electrode 108P. The region 106NS in which the first semiconductor layer 106N is exposed and the region 106PS in which the second semiconductor layer 106P is exposed may be arranged to partially surround the first terminal electrode 108N and the second terminal electrode 108P, rather than surrounding them entirely.

FIG. 4 is a cross-sectional view of a portion of an LED wafer. Specifically, FIG. 4 is an enlarged cross-sectional view cut along the line B1-B2 shown in FIG. 3.

The first terminal electrode 108N may form a contact with the first semiconductor layer 106N. The first terminal electrode 108N may directly or electrically connect with the first semiconductor layer 106N. The second terminal electrode 108P may form a contact with the second semiconductor layer 106P. The second terminal electrode 108P may be directly or electrically connected to the second semiconductor layer 106P. The conductive bonding material layer 110 may be arranged on the top surfaces of the first terminal electrode 108 and the second terminal electrode 108P, respectively. As shown in FIG. 4, a first conductive bonding material layer 110-1 may be arranged on the top surface of the first terminal electrode 108N. A second conductive bonding material layer 110-2 may be arranged on the top surface of the second terminal electrode 108P.

As described above, the LED wafer 10 of one embodiment of the present invention is provided with the conductive bonding material layer 110 on the terminal electrode 108 on the LED element stack 106, so that the LED element stack 106 may be mounted on the LED chip mounting pad without providing the conductive bonding material layer 110 on the LED chip mounting pad on the circuit board 30.

In one embodiment of the present invention described above, the crystalline substrate 100 was used as the substrate supporting the LED element stack 106. However, the substrate supporting the LED element stack 106 is not limited to the crystalline substrate 100.

### Second Embodiment

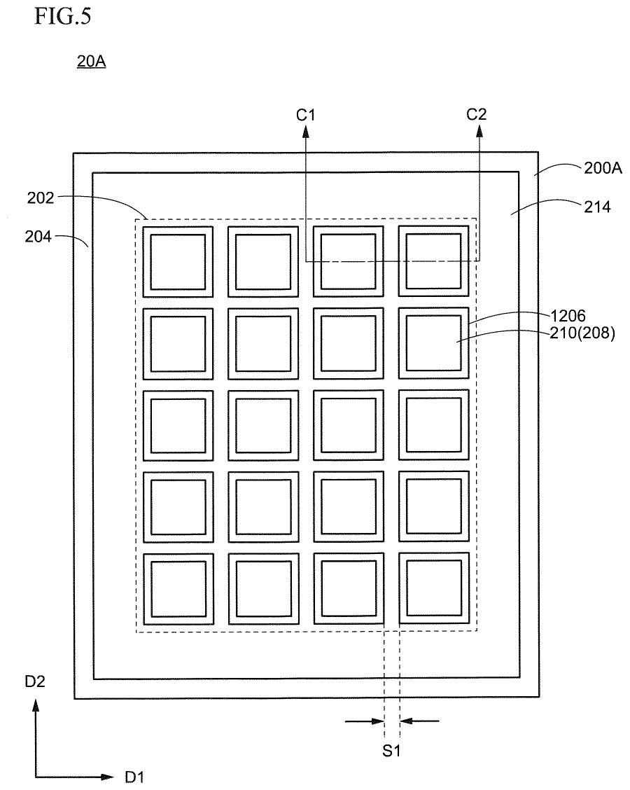

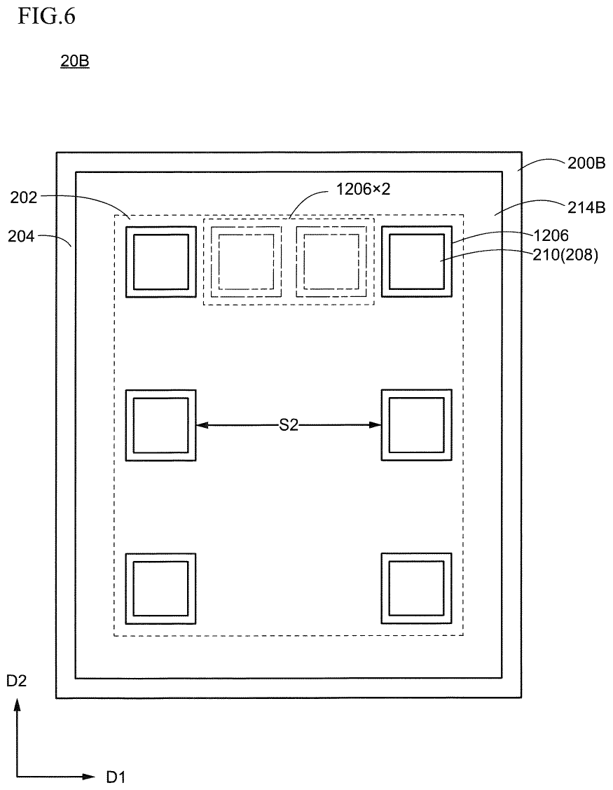

A carrier substrate for an LED chip 20 which is one of the embodiments of the present invention is described while referring to FIGS. 5 and 6.

FIG. 5 is a plan view of a carrier substrate for an LED chip in one embodiment of the present invention. As shown in FIG. 5, a carrier substrate 200A is used in the present embodiment as a substrate to support an LED chip 1206. A carrier substrate for an LED chip 20A shown in FIG. 5 is a carrier substrate obtained by at least two substrate-to-substrate transfers from the LED wafer 10. In other words, the carrier substrate for the LED chip shown in FIG. 5 shows the LED chip from the LED wafer 10 transferred to the primary transfer substrate, and then the LED chip is transferred again from the primary transfer substrate to the carrier substrate 200A. The LED chip 1206 is obtained by individualizing the LED wafer 10 shown in the first embodiment. The carrier substrate for the LED chip 20 has the carrier substrate 200A, the LED chip 1206, and an adhesive layer 214.

The carrier substrate 200A has a region 202 where the 1206 LED chip is arranged and a peripheral region 204 that surrounds the region 202. A plurality of LED chips 1206 may be provided in the region 202. The plurality of LED chips is mutually separated from each other and arranged on the carrier substrate 200A. The plurality of LED chips 1206 are aligned in the first direction D1 (row direction) and the second direction D2 (column direction) shown in FIG. 5, and are arranged in a matrix. The peripheral area 204 may be provided with a marker or the like for use in transferring the LED chips 1206 to other carrier substrates.

An adhesive layer 214 is provided on the carrier substrate 200A. The adhesive layer 214 may be arranged to cover the carrier substrate 200A. The adhesive layer 214 may be arranged to cover the region 202 where the LED chips 1206 are arranged. In FIG. 5, the adhesive layer 214 is shown as a layer that is continuous in the region 202 where the LED chips 1206 are arranged, but it may be separated. For example, the adhesive layer 214 may be provided in the region overlapping the LED chip 1206 and separated from the adhesive layer 214 provided in the region overlapping the adjacent LED chip 1206.

Spacing of the plurality of LED chips 1206 on the carrier substrate 200A may be adjusted. The spacing S1 of the plurality of LED chips 1206 on the carrier substrate 200A may be the same as or wider than the spacing of the plurality of LED element stacks 106 on the crystalline substrate 100 described above. By transferring the plurality of LED chips 1206 between the carrier substrates, the spacing S1 of the plurality of LED chips 1206 may be further widened. For example, if the spacing of the plurality of LED chips 1206 on the carrier substrate 200A is the spacing S1, as shown in FIG. 5, the plurality of LED chips 1206 on the carrier substrate 200A may be transferred to another carrier substrate while thinning, and then further transferred from another carrier substrate to the carrier substrate 200B, so that the spacing S1 of the plurality of LED chips 1206 on the carrier substrate 200B may be adjusted to the spacing S2 which is wider than the spacing S1 of the plurality of LED chips 1206, as shown in FIG. 6. In this case, for example, a plurality of LED chips on the carrier substrate 200A are transferred to an adhesive layer with higher adhesiveness than the adhesive layer 214A on another carrier substrate, and the transferred plurality of LED chips on another carrier substrate are transferred to an adhesive layer 214B with even higher adhesiveness than the adhesive layer on the carrier substrate 200B. By transferring in this way, the spacing S1 may be adjusted. By thinning out the LED chips 1206 per row or per column during the transfer, the spacing S1 may be adjusted to a spacing S2 of, for example, 50 μm to 100 μm. As shown in FIG. 6, for example, the spacing S1 of the plurality of LED chips 1206 may be adjusted to a distance (spacing S2) corresponding to the region×2 (twice) where two LED chips 1206 may be mounted

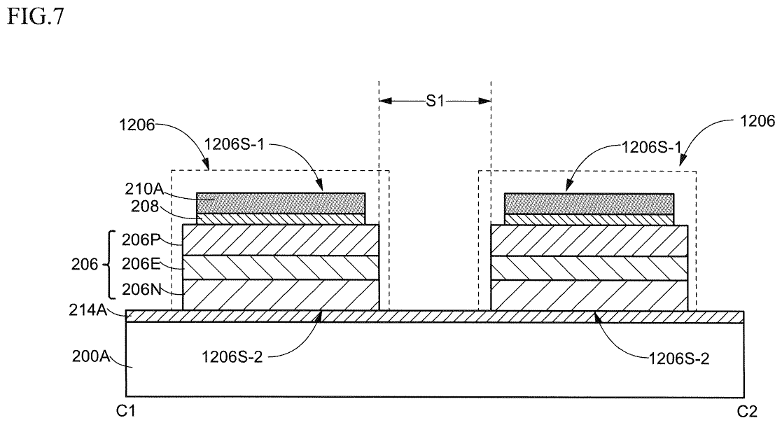

FIG. 7 is a cross-sectional view of a portion of a carrier substrate for an LED chip. Specifically, FIG. 7 is an enlarged cross-sectional view cut along the line C1-C2 shown in FIG. 1.

As shown in FIG. 7, the LED chip 1206 and the adhesive layer 214A are arranged on the carrier substrate 200A. The LED chip 1206 is arranged on the adhesive layer 214A.

The carrier substrate 200A may support each layer provided on the carrier substrate 200A. For example, a substrate having translucency such as a glass substrate, quartz substrate, or resin substrate may be used as the carrier substrate 200A. A flexible substrate such as a polyimide substrate, acrylic substrate, siloxane substrate, or fluoropolymer substrate may be used as the resin substrate. When using laser light to transfer the LED chip 1206 to the circuit board, the carrier substrate 200 should be a translucent substrate that transmits laser light.

The adhesive layer 214A fixes the LED chip 1206 to the carrier substrate 200A. The adhesive layer 214A is arranged between the carrier substrate 200A and the LED chip 1206. A material that may adhere and detach the LED chip 1206 may be used for the adhesive layer 214A. For example, a silicon-based adhesive or a polyimide-based adhesive may be used as the adhesive/removable material. Polydimethylsiloxane (PDMS) and the like may be used for silicone-based adhesives. Polyimide (PI) and the like may be used for polyimide-based adhesives.

The LED chip 1206 includes a semiconductor layer 206, a terminal electrode 208, and a conductive bonding material layer 210 on the terminal electrode 208. The LED chip 1206 is arranged on the carrier substrate 200A with a surface on which the conductive bonding material layer 210 is provided as a top surface 1206S-1 and a surface on which the adhesive layer 214 is provided as a bottom surface 1206S-2. A plurality of LED chips 1206 may be provided on the carrier substrate 200A, and the plurality of LED chips 1206 may be separated from each other and arranged on the carrier substrate 200A.

The semiconductor layer 206 is a stacked layer of a first semiconductor layer 206N having a first conductivity type, a light-emitting layer, and a second semiconductor layer having a second conductivity type opposite to the first conductivity type. The semiconductor layer 206 may be arranged on an adhesive layer 214A. The first semiconductor layer 106N, the light emitting layer 106E, and the second semiconductor layer 106P may be the same as the layers used in the LED element stack 106 described above.

The terminal electrode 208 forms a contact with the first semiconductor layer 206N or the second semiconductor layer 206P. The terminal electrode 208 may be directly or electrically connected to the first semiconductor layer 106N or the second semiconductor layer 106P. The terminal electrode 208 may be arranged on the semiconductor layer 206. The terminal electrode 208 may be the same as the terminal electrode 108 used for the LED wafer 10 described above.

The conductive bonding material layer 210 may be arranged on the terminal electrode 208. The conductive bonding material layer 110 may be the same as the conductive bonding material layer 110 used for the LED wafer 10 described above.

In one embodiment of the present invention described above, the first semiconductor layer 206N having a first conductivity type, the light-emitting layer 206E, and the second semiconductor layer 206P having a second conductivity type opposite to the first conductivity type are stacked on the carrier substrate 200A, and the terminal electrode 208 forms a contact with the first semiconductor layer 206N or the second semiconductor layer 206P, and the LED chip 1206 has a so-called vertical structure. However, the connection between the LED chip 1206 and the terminal electrode 208 is not limited to the connection of the vertical structure.

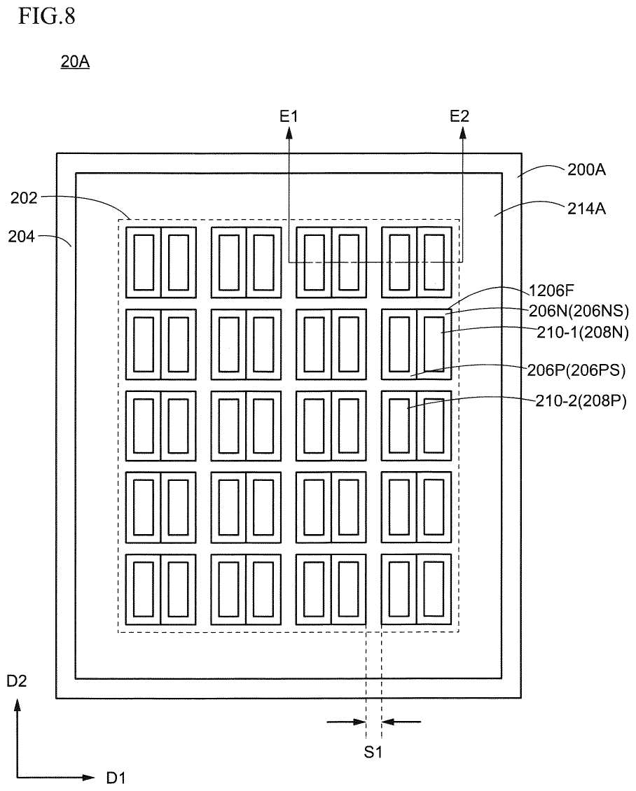

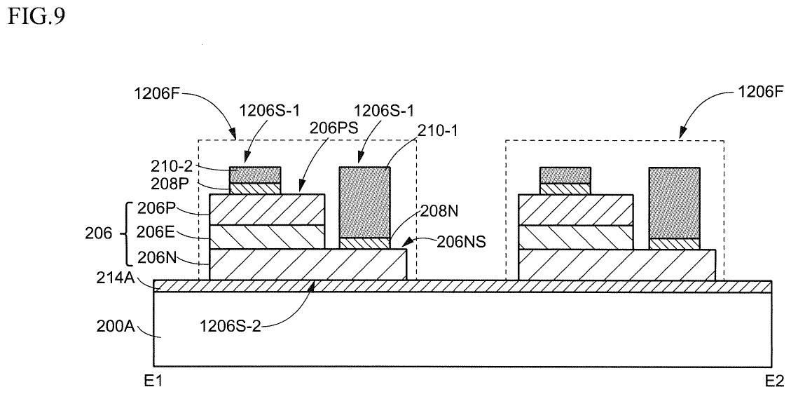

FIG. 8 is a plan view of a carrier substrate for an LED chip 20 according to one embodiment of the present invention. As shown in FIG. 8, the LED chip 1206 in the present embodiment has a flip-type structure with two terminal electrodes 108N and 108P in a plan view. In FIGS. 8 and 9, the same reference numbers are attached to the same configuration of the LED chip 1206 shown in FIGS. 6 and 7, and redundant explanations are omitted.

An LED chip 1206F may have, in a plan view, a region 206NS where the first semiconductor layer 206N is exposed and a region 206PS where the second semiconductor layer 206P is exposed and may include a first terminal electrode 208N and a second terminal electrode 208P. As shown in FIG. 8, the region 206NS where the first semiconductor layer 206N is exposed may be adjacent to the region 206PS where the second semiconductor layer 206P is exposed. The region 206NS where the first semiconductor layer 206N is exposed may be arranged to surround the first terminal electrode 208N. The region 206PS where the second semiconductor layer 206P is exposed may be arranged to surround the second terminal electrode 208P. The region 206NS where the first semiconductor layer 206N is exposed and the region 206PS where the second semiconductor layer 206P is exposed may be arranged to partially surround the first terminal electrode 208N and the second terminal electrode 208P, rather than surround them entirely.

FIG. 9 is a cross-sectional view of a portion of an LED wafer according to one embodiment of the present invention. Specifically, FIG. 9 is an enlarged cross-sectional view cut along the line E1-E2 shown in FIG. 9.

The first terminal electrode 208N may form a contact with the first semiconductor layer 206N. The first terminal electrode 208N may directly or electrically connect with the first semiconductor layer 206N. The second terminal electrode 208P may form a contact with the second semiconductor layer 206P. The second terminal electrode 208P may be directly or electrically connected to the second semiconductor layer 206P. The conductive bonding material layer 210 may be arranged on the top surfaces of the first terminal electrode 208N and the second terminal electrode 208P, respectively. As shown in FIG. 9, a first conductive bonding material layer 210-1 may be arranged on the top surface of the first terminal electrode 208N. A second conductive bonding material layer 210-2 may be arranged on the top surface of the second terminal electrode 208P.

As described above, in the carrier substrate for the LED chip 20, the LED chip 1206 can be mounted on the LED chip mounting pad without providing the conductive bonding material layer 210 on the LED chip mounting pad on the circuit board 30 by providing the conductive bonding material layer 210 on the terminal electrode 208.

### Third Embodiment

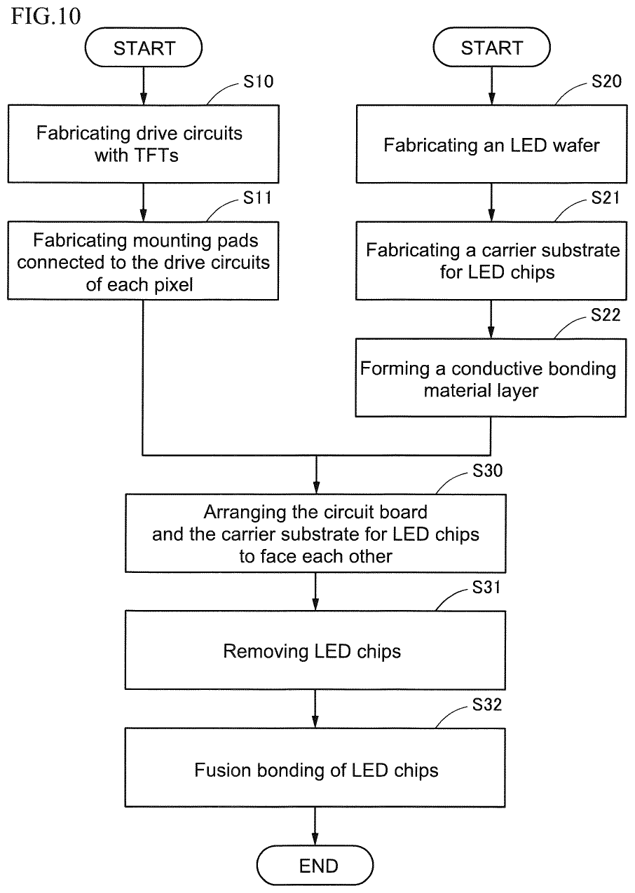

A manufacturing method for a display device as one embodiment of the present invention will be described while referring to FIGS. 10 to 13. Descriptions may be omitted for configurations identical or similar to those described in the first or second embodiments.

### Manufacturing Method for Display Device

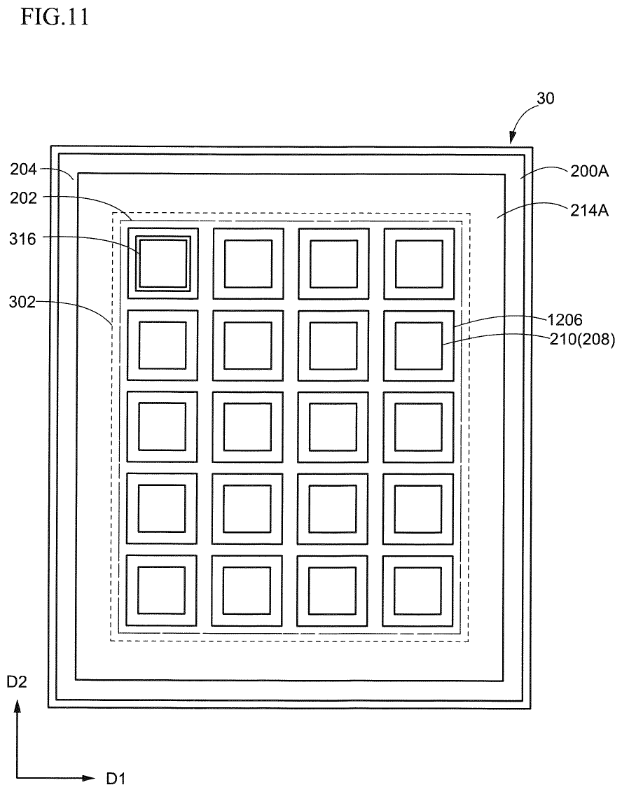

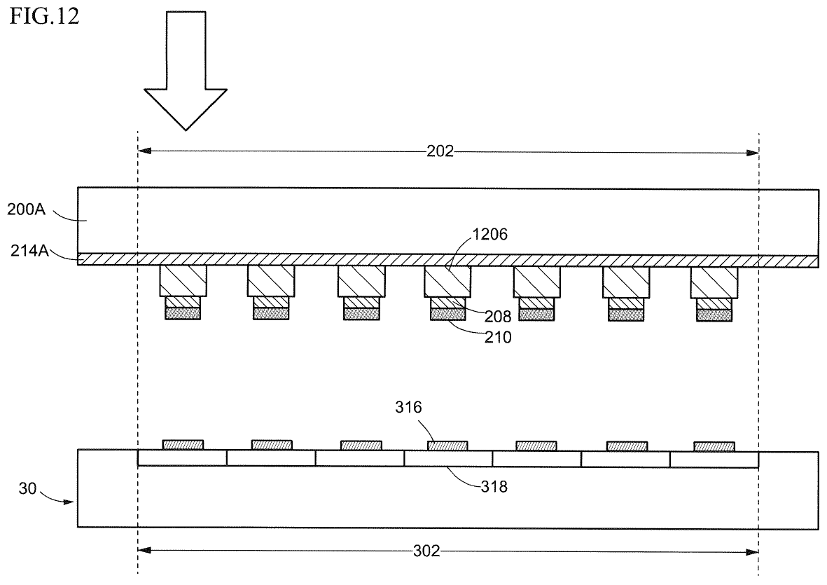

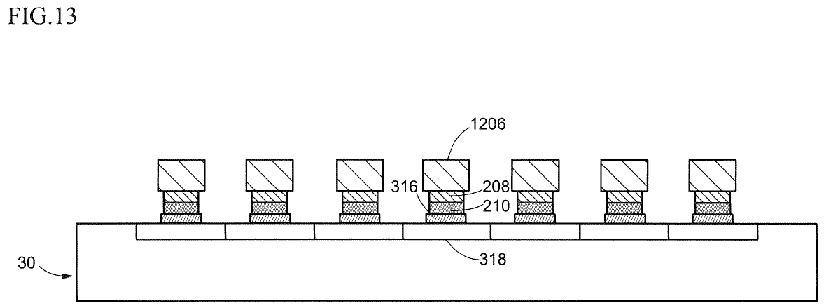

FIG. 10 is a flowchart diagram showing a manufacturing method for a display device. Specifically, FIG. 10 shows the process of mounting a plurality of LED chips 1206 on a circuit board. FIG. 11 is a plan view of the manufacturing method for a display device according to one embodiment of the present invention. FIGS. 12 and 13 are cross-sectional views of a manufacturing method for a display device according to one embodiment of the present invention. In FIGS. 11 and 12, the LED chip 1206 shown in FIG. 7 is shown in a simplified configuration.

### (Fabrication Process of Circuit Board)

First, in step S10 of FIG. 10, a drive circuit 318 for causing an LED to emit light using a thin-film transistor (TFT) is fabricated at a location corresponding to each pixel. These drive circuits 318 are electrically connected to each LED chip 1206. Next, in step S11 of FIG. 10, a mounting pad is fabricated to electrically connect the drive circuit 318 fabricated at the position corresponding to each pixel to the LED chip 1206.

### (Fabrication Process of Carrier Substrate for LED Chip)

In step S20 of FIG. 10, the LED element stack 106 is fabricated on the LED wafer 10, and the terminal electrode 108 is formed on the LED element stack 106. Next, in step S21 of FIG. 10, the LED element stack 106 is transferred from the LED wafer 10 to the carrier substrate 200A to fabricate the LED chip 1206. Further, in step S22 of FIG. 10, the conductive bonding material layer 110 is formed on the LED chip 1206 on the carrier substrate 204A.

(Mounting process of LED chips)

Next, in step S30 of FIG. 10, the carrier substrate 200A is arranged to face the circuit board 30, and the circuit board 30 and the carrier substrate for the LED chip 20 are aligned. Specifically, as shown in FIG. 11, in a plan view, the circuit board 30 and the carrier substrate for the LED chip 20 are aligned so that a mounting pad 316 provided for each pixel in a pixel region 302 of the circuit board 30 and at least one LED chip 1206 arranged in the region 202 of the carrier substrate 200 overlap.

In a cross-sectional view, for example, as shown in FIG. 12, the circuit board 30 and the carrier substrate for the LED chip 20 are aligned so that the mounting pad 316 provided in each pixel of the pixel region 302 of the circuit board 30 and the LED chip 1206 overlap.

Next, in step S31 of FIG. 10, the LED chip 1206 is removed from the carrier substrate 200A. For example, as shown in FIG. 12, laser light (arrow) is irradiated on the adhesive layer 214A or the LED chip 1206 to remove the LED chip 1206 from the carrier substrate 200A. At this time, the removed LED chip 1206 is transferred onto the mounting pad 316 of each pixel.

Alternatively, for example, the carrier substrate for the LED chip 20 is pressed against the circuit board 30, and the conductive bonding material layer 210 of the LED chip 1206 is adhered to the mounting pad 316 of the circuit board 30. Furthermore, for example, the conductive bonding material layer 210 or the mounting pad 316 is heated by laser irradiation or the like to fuse the conductive bonding material layer 210 and the mounting pad 316. Finally, as shown in FIG. 13, the carrier substrate 200 is pulled up and the LED chip 1206 is removed from the carrier substrate 200. Here, before pulling up the carrier substrate 200, the adhesive layer 214 may be removed from the LED chip 1206 or the carrier substrate 200 to separate the LED chip 1206 and the carrier substrate 200.

Finally, in step S32 of FIG. 10, the LED chip 1206 is fused to the mounting pad 316. The LED chip 1206 is fused and bonded to the mounting pad 316 corresponding to each pixel of the circuit board 30 by melting at least a part of the conductive bonding material layer 210 and then curing it.

The processes of fabricating the circuit board, fabricating the carrier substrate for the LED chip, and mounting the LED chip on the circuit board may be used to manufacture a display device with a structure in which the conductive bonding material layer 210 contacts the mounting pad 316 of the circuit board 30.

The fabrication process for the circuit board, the fabrication process for the carrier substrate for the LED chip, and the process for mounting the LED chip on the circuit board may be carried out as a single process, or a separately manufactured carrier substrate for the LED chip may be provided for the circuit board manufactured in the processes described above, and the mounting process may be carried out.

As described above, in the manufacturing method for the display device, by using the carrier substrate for the LED chip 20, which includes the conductive bonding material layer 210 on the top surface 1206S-1 of the at least one LED chip 1206 and the adhesive layer 214 on the bottom surface 1206S-2 of the at least one LED chip 1206, the LED chip 1206 is mounted on the circuit board 30. Then, the LED chip 1206 can be mounted on the circuit board 30 without providing the conductive bonding material layer 210 on the mounting pad 316.

### Fourth Embodiment

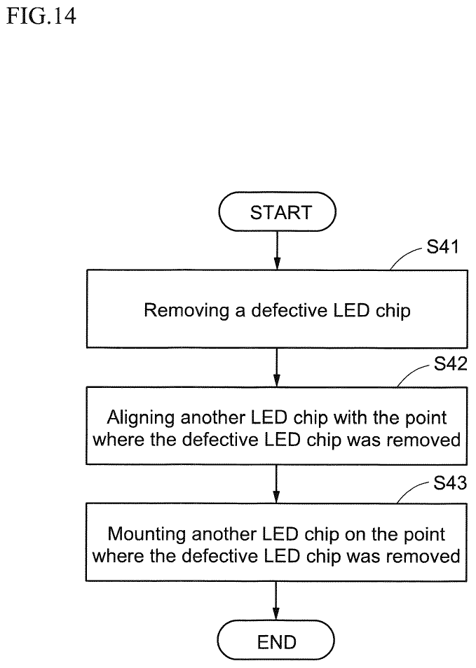

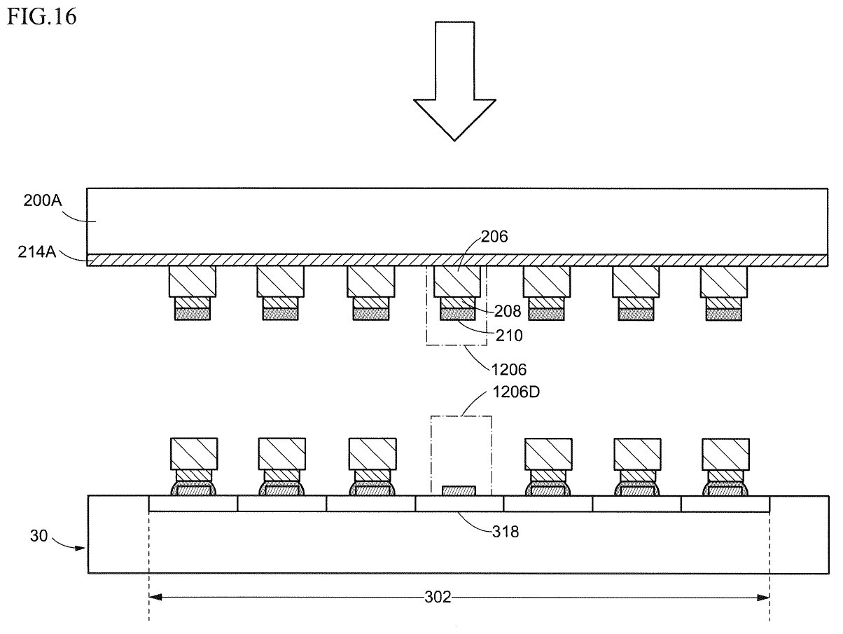

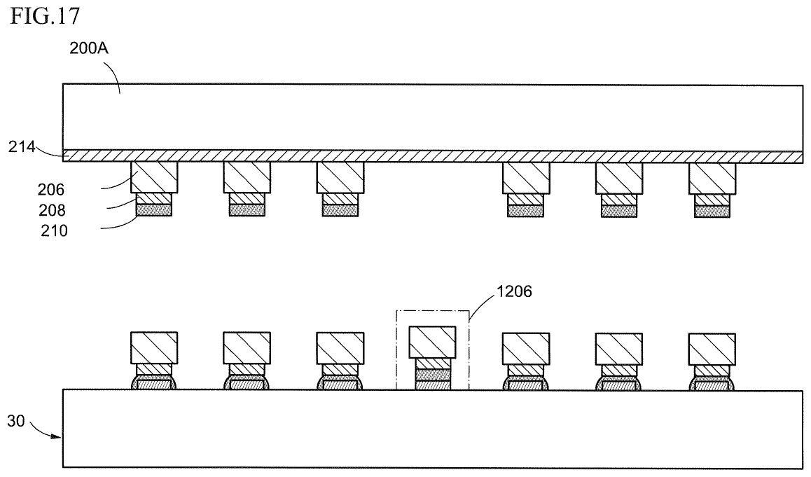

A repair method for a display device in one of the embodiments of the present invention will be described while referring to FIGS. 14 to 17. Descriptions may be omitted for configurations identical or similar to those described in the first through third embodiments.

### (Repair Method for Display Device)

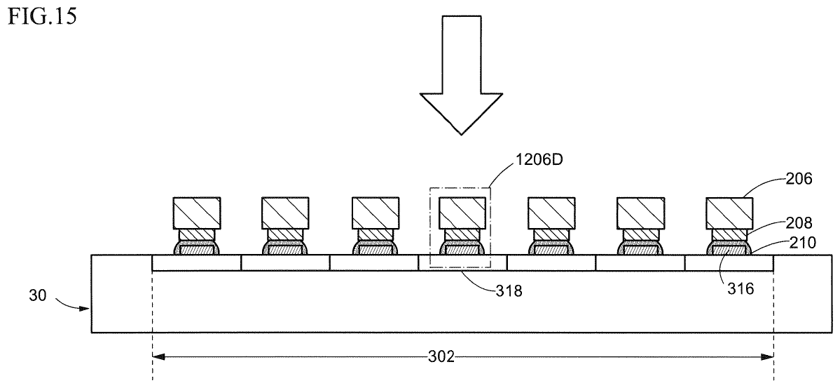

FIG. 14 is a flowchart diagram showing a repair method for a display device. Specifically, FIG. 14 shows the process of removing an LED chip 1206D that is determined to be defective on the circuit board 30, and mounting an LED chip 1206 from the carrier substrate 200A on a point where the LED chip 1206D was removed in the circuit board 30. FIGS. 15 to 17 are cross-sectional views showing a repair method for a display device according to an embodiment of the present invention. In FIGS. 15 to 17, the LED chip 1206 shown in FIG. 7 is shown in a simplified configuration. It is assumed that the LED chip 1206 is mounted in each pixel on the circuit board 30.

First, in step S41 of FIG. 14, the LED chip 1206D that is determined to be defective is removed from the circuit board 30. For example, among the plurality of LED chips 1206D provided in the pixel region 302 in the circuit board 30 shown in FIG. 14, laser light (arrow) is irradiated to the LED chip 1206D that is determined to be defective, and the LED chip 1206D is removed from the circuit board 30. After removing the LED chip 1206D determined to be defective, further processing may be performed to expose the mounting pad 316 provided at the point where the LED chip 1206D was removed. As a method of exposing the mounting pad 316, for example, laser light irradiation on the mounting pad 316 may be used.

Next, in step S42 of FIG. 14, the LED chip 1206D is aligned with the LED chip 1206 on the carrier substrate 200A at the point where the LED chip 1206D was removed. Specifically, the conductive bonding material layer 110 of the LED chip 1206 on the carrier substrate 200A is aligned with the mounting pad 316 after the LED chip 1206D was removed.

Furthermore, in step S43 of FIG. 14, the LED chip 1206 on the carrier substrate 200A is mounted at the point where the LED chip 1206D has been removed. The same method as steps S30 to S32 in FIG. 10 may be used to mount the LED chip 1206 on the circuit board 30.

A carrier substrate 200B with a wide spacing S2 between the LED chips 1206 as shown in FIG. 6 may be used for the carrier substrate 200A. The use of the carrier substrate 200B with wide spacing S2 between LED chips 1206 enables mounting of new LED chips on the circuit board 30 without interference with the LED chips 1206 placed outside of the repaired point.

As described above, the repair method for the display device includes the conductive bonding material layer 110 on the top surface 1206S-1 of at least one LED chip 1206 and the adhesive layer 214 on the bottom surface 1206S-2 of at least one LED chip 1206. By using the carrier substrate for LED chips 20, a new LED chip can be easily placed on the mounting pad from which the LED chip determined to be defective has been removed. In this case, the conductive bonding material layer 210 is provided on the LED chips 1206 of the carrier substrate 200A so that a fine LED chip can be easily replaced for irregularly occurring defective points without the need to provide a conductive material for bonding on the circuit board 30.

In addition, by reusing the mounting pad from which the LED chip was removed, there is no need to provide a spare LED chip mounting pad in the pixel provided on the circuit board 30, which enables pixel miniaturization.

Each of the embodiments described above as an embodiment of the present invention can be appropriately combined and implemented as long as they do not contradict each other. The addition, deletion, or design change of components as appropriate, or the addition, deletion, or condition change of processes by those skilled in the art based on each embodiment are also included in the scope of the present invention as long as they are provided with the gist of the present invention.

Further, it is understood that, even if the advantageous effect is different from those provided by each of the above-described embodiments, the advantageous effect obvious from the description in the specification or easily predicted by the person skilled in the art is apparently derived from the present invention.

What is claimed is:

1. An LED wafer comprising:
an LED element stack including a first semiconductor layer having a first conductivity type, a light-emitting layer, and a second semiconductor layer having a second conductivity type opposite to the first conductivity type stacked on a crystalline substrate;
a terminal electrode forming a contact with the first semiconductor layer or the second semiconductor layer, and
a conductive bonding material layer on the terminal electrode.

2. The LED wafer according to claim 1, wherein
the crystalline substrate is a sapphire or gallium nitride substrate.

3. The LED wafer according to claim 1, wherein
an LED element stack comprises a plurality of LED element stacks, and
the plurality of LED element stacks is mutually separated from each other by a separation groove.

4. The LED wafer according to claim 1, wherein
the LED element stack has a region where the first semiconductor layer is exposed and a region where the second semiconductor layer is exposed, in a plan view,
the terminal electrode includes a first terminal electrode and a second terminal electrode,
the first terminal electrode forms a contact with the first semiconductor layer, and the second terminal electrode forms a contact with the second semiconductor layer, and
the conductive bonding material layer is arranged on the top surface of the first terminal electrode and the second terminal electrode, respectively.

5. A carrier substrate for an LED chip comprising:
a carrier substrate;
an LED chip on the carrier substrate, and
an adhesive layer between the carrier substrate and the LED chip,
wherein
the LED chip comprises,
a semiconductor layer comprising a first semiconductor layer having a first conductivity type, an emission layer, and a second semiconductor layer having a second conductivity type opposite to the first conductivity type,
a terminal electrode forming a contact with the first semiconductor layer or the second semiconductor layer, and
a conductive bonding material layer on the terminal electrode,
the LED chip is arranged on the carrier substrate with a surface on which the conductive bonding material layer is provided as a top surface, and
the LED chip is fixed to the carrier substrate by the adhesive layer.

6. The carrier substrate according to claim 5, wherein
the LED chip comprises a plurality of LED chips, and
the plurality of LED chips is mutually separated from each other by a separation groove.

7. The carrier substrate according to claim 5, wherein
the LED chip has a region where the first semiconductor layer is exposed and a region where the second semiconductor layer is exposed, in a plan view,
the terminal electrode includes a first terminal electrode and a second terminal electrode,
the first terminal electrode forms a contact with the first semiconductor layer, and the second terminal electrode forms a contact with the second semiconductor layer, and
the conductive bonding material layer is arranged on a top surface of the first terminal electrode and the second terminal electrode, respectively.

8. A manufacturing method for a display device comprising:
aligning a mounting pad and a conductive material layer to overlap in a plan view while arranging a carrier substrate for an LED chip, including a carrier substrate, an LED chip on the carrier substrate, a conductive bonding material layer on a first surface of the LED chip, an adhesive layer on a second surface of the LED chip, to face a circuit board including a mounting pad corresponding to a pixel in a pixel region;
removing the LED chip from the carrier substrate, and
fusing the at least one LED chip to the mounting pad by melting and curing a part of the conductive bonding material layer.

9. A repair method for a display device comprising:
removing a first LED chip on a circuit board including a plurality of LED chips in a pixel region, which is arranged on a mounting pad at a first point of a first pixel in the pixel region and which is determined to be defective among the plurality of LED chips;
aligning a conductive bonding material layer and the mounting pad to overlap, in which a carrier substrate for an LED chip, including a carrier substrate, an LED chip on the carrier substrate, the conductive bonding material layer on a first surface of the LED chip, and an adhesive layer on a second surface of the LED chip;
removing the LED chip from the carrier substrate, and
fusing the LED chip to the mounting pad by melting and curing a part of the conductive bonding material layer.

10. The repair method according to claim 9, further comprising,
exposing the mounting pad at the first point after the removing the first LED chip.
